(19) United States
(12) Patent Application Publication
(10) Pub. No.: US 2018/0358586 A1
(43) Pub. Date: Dec. 13, 2018

(54) IMPROVED LIGHT EMISSION IN OLEDS

(71) Applicants: Nederlandse Organisatie voor toegepast-natuurwetenschappelijk onderzoek TNO, 's-Gravenhage (NL); Dupont Teijin Films U.K. Limited, Middlesbrough, Cleveland (GB)

(72) Inventors: Stephan Harkema, 's-Gravenhage (NL); Duncan Henry MacKerron, Middlesbrough, Cleveland (GB); Sami Sabik, 's-Gravenhage (NL); Rajesh Mandamparambil, s'-Gravenhage (NL)

(21) Appl. No.: 16/060,101

(22) PCT Filed: Dec. 8, 2016
(86) PCT No.: PCT/NL2016/050857

§ 371 Date: Jun. 7, 2018

(30) Foreign Application Priority Data
Dec. 8, 2015 (EP) 15198469.7

(51) Int. Cl. H01L 51/56; H01L 51/50; H01L 51/52; H01L 51/00

(52) U.S. Cl. CPC H01L 51/56; H01L 51/5056; H01L 51/5072; H01L 51/0009; H01L 51/5215; H01L 51/5218; H01L 51/5092

(57) ABSTRACT

Improved light emission in OLEDs The invention relates to an organic light-emitting diode (OLED) system comprising a multi-layered structure having a semiconducting organic layer (12) sandwiched between first and second electrodes (3a, 3b); further comprising a barrier layer (6) interposed between the semiconducting organic layer and a polymer substrate (1) having formed an random nanopillar structure thereon having a pillar height dimension between 50 and 1000 nanometer and a pitch in a range of 50-1000 nanometer.

### FIELD

The invention relates to an OLED arranged to emit light having different colours, comprising a multi-layered structure provided with a first electrode, a second electrode and a functional layer enabling light emission disposed between the first electrode and the second electrode.

The invention further relates to an electronic device comprising such an OLED. The invention further relates to a method of manufacturing an OLED.

### BACKGROUND

OLEDs have a high potential efficiency, but in practice a much lower efficiency due to their planar nature. OLEDs can be made more efficient by improving light extraction at the exterior. For example, in a standard bottom emitting OLED about 50% of the generated photons are dissipated as wave guided modes and 20-30% as plasmonic modes or cathode quenching. In addition, mirror surfaces by their nature have a tendency to prevent outcoupling of light waves traveling above the grazing angle. One approach is to add optical structures, to mitigate this trapping effect. However, these methods are typically diffusive in nature and thus visible to the naked eye, which is considered undesirable. Light diffusing layers can also be applied in the interior of the device (between substrate and anode). Nevertheless, they generally take away the mirror appearance of OLEDs. Another method is obtained by introducing periodic structures on the exterior or interior of the OLED, which may be mirror like, due to their nanometer geometry. Such photonic crystals help with light extraction as well by a mechanism called Surface Plasmon Polariton (SPP) harvesting, but are usually only specific to a single wavelength. Worse, photonic crystals are also often visible if periodic in nature. The periodicity is visible by bright diffraction colors that are caused by the interaction of light with this structure. Such patterns are usually made with nano-imprint lithography, which is commercial, but not typical to apply because of the high costs and high amount of defects that occur during processing. A multi-wavelength photonic structure is much more difficult to realize, although this has been attempted & modelled. Since non-periodic photonic crystals are expected to be highly inefficient in OLEDs, they are not applied H. Greiner, O.J.F. Martin, Numerical Modelling of Light Emission and Propagation in (Organic) LEDs with the Green's Tensor, Proceedings of the SPIE, Vol.5214, pp.248-259. Still, a desire exists to provide a simple and efficient way for improving light extraction for multi wavelength, in particular white light OLEDS. An embodiment of an OLED capable of emitting light having various colours is known from WO 2006/087654. In the known OLED an anode layer is provided on a suitable substrate, which is followed by a hole-injection layer followed by a layer of a light emissive material, having certain thickness along the substrate, above which a cathode layer is deposited. In literature, devices with photonic crystals show additional features in the EL response, for instance those published in J. Appl. Sci. 2004, vol 96, page 7629 by Y. R. Do et al.

In US20130181242 a random structure is provided by a dewetting process of a metal layer, yielding a nano embossing structure by etching the thus formed irregular mask of the metal layer that has a partial diffraction effect. The step of applying a metal layer, carrying out a dewetting process, carrying out the etching step and removing the layer is cumbersome and in practice difficult to control.

In WO2015147294 a surface roughness is created by an etching process of an organic layer having inorganic filler particles for optimizing luminous efficiency. The specification focuses on special transparent substrates that are provided by sheets of acrylic resin. In practice, the step of providing such kind of substrates in an industrial process is cumbersome.

### SUMMARY OF THE INVENTION

It is aimed to provide an efficient way of providing a transparent substrate that treated to enhance the luminous outcoupling of an OLED, that can be provided in an industrial manner.

To this end, a method is provided including the steps of providing a transparent polymer substrate, such as PET or PEN;
forming a random nanopillar structure thereon with a pillar height dimension between 50 and 1000 nanometer and a pitch in a range of 50-1000 nanometer, by an ablation process;
providing a transparent coating of thickness 100 nm-30 microns having a refractive index matching an inorganic barrier layer; and
providing the inorganic barrier layer.

According to a further aspect an OLED is provided according to the features of the independent claim. In particular, an organic light-emitting diode (OLED) system comprises a multi-layered structure with a semiconducting organic layer sandwiched between first and second transparent or reflective electrodes. The OLED further comprises a barrier layer interposed between the electrode and a polymer substrate. The polymer substrate has formed thereon a random nanopillar structure with a pillar height dimension between 50 and 1000 nanometer and a pitch in a range of 50-1000 nanometer. The substrate with nanopillar structures may be light transmissive or may be reflective, e.g. covered with a metallic film to add a reflective interface with nanostructures. Such a device would require a transparent top electrode to be emissive.

The afore mentioned random pillar structures can be prepared by a reactive ion etching step in a ‘mild etch condition’ of an organic layer or substrate, such as PET or PEN, preferably of heat-stabilized nature—which is a procedure per se known by skilled persons. More preferably, deposition of a moisture barrier is provided onto the nano-topology of the nanopillar structure comprises printing or coating of the organic, with a refractive index of at least 1.5, preferably at least 1.7, with a pattern coinciding with the intended opto-electronic device, or full area, and covered in a continuous process by PE CVD or spatial ALD for thin inorganic materials with preferably a refractive index of at least the value of the substrate, more preferably exceeding 1.7

Even more preferably the method is carried out in a roll to roll process, comprising the step of providing the transparent polymer substrate on a roll; unrolling the polymer substrate; carrying out the steps of claim 1, and winding the provided inorganic barrier layer on a roll.

The resultant is an assembly of nanostructures that are sub-wavelength in width and height (e.g. 100 nm wide and 100 nm high). By changing the conditions of RIE, the height of the structures can be tuned. The higher the structure, the more effective for light extraction. Without being bound to theory, the nanostructure may be caused by particles in the organic layer or substrate that shield the matrix from the bombardment of reactive species during RIE and/or amorphous, crystalline domains in the polymer. Also, by tuning these particles and/or domains, the topology of the pillar structure may be tuned.

It is noted that these type of treatments are known for various applications, such as e.g. described in ‘plasma treatment of polymers for surface and adhesion improvement’ Hegeman et al, Nuclear Instruments and Methods in Physics Research B 208 (2003) 281-286; Modification of the micro- and nanotopography of several polymers by plasma treatments, Coen et al Applied Surface Science 207 (2003) 276-286. Surface modification and ageing of PMMA polymer by oxygen plasma treatment, Vesel et al, Vacuum 86 (2012) 634-637; Ultrahydrophobic PMMA micro- and nano-textured surfaces fabricated by optical lithography and plasma etching for X-ray diffraction studies, Accardo et al, Microelectronic Engineering 88 (2011) 1660-1663; Antireflection of transparent polymers by advanced plasma etching procedures, Schultz et al, 1 Oct. 2007/Vol. 15, No. 20/OPTICS EXPRESS 13108. However, none of these publications concern with the problem of enhancing the OLED light output without compromising the transparency of the substrate.

In an embodiment the texture may be covered with a coating with similar or higher refractive index than the underlying substrate, a barrier layer of sufficient density and moisture sealing properties (e.g. SiN layer or barrier stack), an OLED, a cathode and finally encapsulation. Accordingly a scalable and easy method to introduce a texture on plastic polymerized substrates is provided that is effective for light out-coupling. The texture is invisible to the naked eye, which is of great benefit to companies that value the pristine mirror-like appearance of OLEDs.

Throughout the application, the term “sandwich” in “sandwiched layer” is used, unless otherwise indicated, to indicate that a layer is formed between two other layers, i.e. sandwiched there between, without necessarily being adjacent i.e. in direct physical contact to each other. Thus in a stack having subsequent (adjacent) layers numbered 1, 2, 3 and 4, layer 2 is sandwiched between layers 1 and 3 but also between layers 1 and 4. Layer 1 is however not sandwiched between layers 2 and any of subsequent layers 3 or 4. Reactive ion etching is easy to apply and for example described in Cheng-Yao Lo “Optimization of plasma preparation of polymeric substrate for embedded flexible electronic applications” Microelectronic Engineering 88 (2011) 2657-2661, where similar etching is demonstrated for improving the wetting angle. In an embodiment, a PEN foil was placed in a chamber that was filled with argon gas, CHF3 gas and oxygen. Fast or slow etching was achieved by varying the gas composition, applied power and time. 100 nm high structures were already successful in light extraction, which can be achieved in a few seconds to minutes. No cover or pre-treatment was necessary. It may be favorable to post-treat the foil. The RIE texture has a significant improvement in out-coupling, even when applied a little. Weak etch conditions resulted in small features (50-100 nm high) and still gave 30% enhancement in brightness. Still, the PEN foil was unaffected to the naked eye. AFM or SEM were required to make the nano-structure visible.

The structure appeared to have a similar behavior on the OLED as a 2D photonic structure would, e.g. of the type described in [T. Schwab et al., Optics Express 2014, 22 (7), 7524], however, the pillar structures are irregular and random, in contrast to the predesigned structures such as gratings, or (a) periodic crystal structures. The electroluminescence response showed clear signs of a redirection of emission into forward directed angles. Nevertheless, the foil is fully transparent and not at all colourful and has a transmission that appears unaffected in the visible wavelength range.

It will be appreciated that the method of invention may comprise the step of depositing further layers of the diode. In particular, when the semiconducting organic layer comprises a plurality of sublayers, such as a light-emitting layer superposed on the hole injection and/or transport layers or the electron injection and/or transport layers, the method according to the invention comprises the step of depositing the light emitting layer in addition to said hole injection and/or transport layers and/or said electron injection and/or transport layers.

In an embodiment of the method according to the invention the first electrode layer and/or the second electrode may be reflective, partially reflective or fully transmissive for visible wavelengths, in particular, for the OLED-produced radiation. Alternatively, for the substrate a reflective material deposited on a plastic foil may be used after the nano-pillar structure is created. It will be appreciated that a semi-transparent reflective interface will transmit a substantial part of the light, i.e. more than 10%, or even more than 50% of the visible light.

These and other aspects of the invention will be discussed in more detail with reference to drawings, wherein like reference numerals refer to like elements. It will be appreciated that the drawings are presented for illustrative purposes and may not be used for limiting the scope of the appended claims.

### BRIEF DESCRIPTION OF THE DRAWINGS

FIG. 1A presents in a schematic way an embodiment of a cross-section of an OLED according to the invention;

FIG. 1B presents an exemplary OLED stack that also is the reference stack;

FIG. 2 (A+B) shows two SEM images of a polymer substrate, treated with an ablation process according to an aspect of the invention.

FIG. 3 (A+B+C) shows exemplary k-space plots for periodic and random structures;

FIG. 4 shows a measured outcoupling for the exemplary embodiment, in comparison with an untreated comparative embodiment.

FIG. 5 shows an example, wherein nano pillar structures are not planarized by the refractive coating and barrier layer.

### DETAILED DESCRIPTION OF THE DRAWINGS

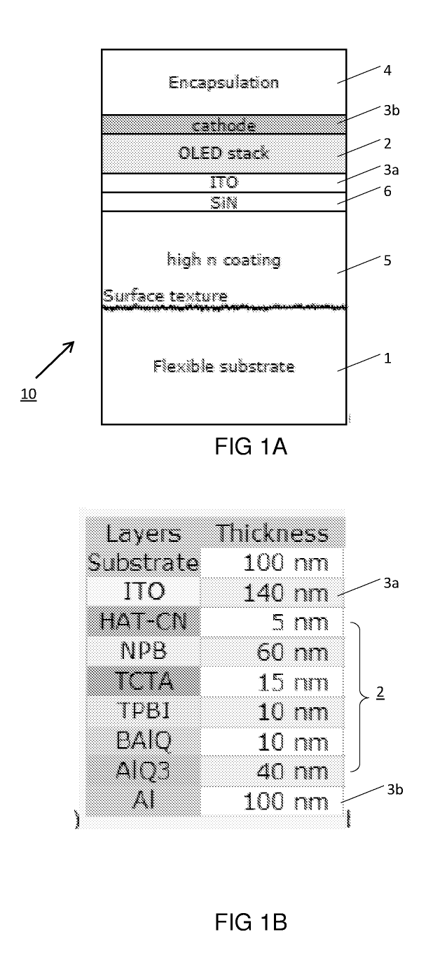

FIG. 1 presents in a schematic way an embodiment of a cross-section of an OLED according to the invention. In the organic light-emitting diode (OLED) a multi-layered structure 10 is provided having a semiconducting organic layer 2 sandwiched between first and second electrodes 3a, 3b. FIG. 1A illustrates a bottom emission OLED device that emits through a transparent anode 3a that is created on a plastic substrate. Electrode 3b serves as the cathode is highly reflective. Alternatively, cathode 3b could be formed by a layer combination that generates a semi-transparent reflective layer, or even a fully transparent layer, e.g. that is formed by a transparent conductive layer, which may include layers formed from transparent conductive oxides, nanowires, nanoparticles, and other materials combinations that provide the same n a further aspect of the invention, a flexible substrate 1 is provided with a surface texture that forms an irregular random nanopillar structure obtainable by selective etching or thermal/radiative treatment of the organic substrate surface. In one example, the PET or PEN can be laminated onto a glass substrate with a glue by a sheet-to-sheet process. The PET or PEN is then put in a RIE chamber and etched. The structure may be post- processed to remove debris (e.g. remove with sacrificial sticky foil). A refractive coating 5 is then put onto the substrate 1. This coating 5 is preferably of similar or high refractive index, e.g. n>1.5 (n is refractive index), preferably even of n larger or equal to 1.8 (also 1.7 may be used, e.g. polyimide). Coating 5 preferably does not absorb the visible OLED radiation. Polyimide was proven to be sufficiently transparent (special type as was commercially obtained from Brewer Sci). The n=1.8 layer was also fully transparent. The refractive coating 5 was subsequently coated with an inorganic barrier layer 6 a with matching refractive index, e.g. PE-CVD SiN. SiN is preferably adapted to have a relatively low refractive index and near 0 extinction coefficient by incorporating hydrogen. Barrier coating 6 may be formed by a stack of inorganic/organic/inorganic barrier layers e.g. of the type as disclosed in EP2924757. Barrier coating 6 or coatings is then covered with an anode 3a, e.g. ITO, and the OLED. In the example as disclosed, the OLED is green light-emitting, but the random nature of the RIE texture makes it suitable for any wavelength in the visible spectrum or even beyond that. The organics of the OLED are covered with a cathode 3a, which may be highly reflective (e.g. Al, Ag; here used is Al) or (semi-) transparent (e.g. TCO, metal nano-particles, nano-wires, graphene, etc.) in order to create a transparent device. The device 10 is sealed, for instance with a (thin film) encapsulation stack 4. Optional is to add external light diffusing layers, but this will affect the appearance.

The invention is not specifically tied to a particular OLED structure, that can be top emissive or bottom emissive. By way of illustration, Figure lb gives an exemplary stack that also functions as a reference stack when the substrate is glass. The OLED stack used in the experiment emits green light from an Ir(ppy)3 emitter that is co-evaporated in TPBI and TCTA. The stack consists of HAT-CN as hole-injection material, NPB as hole transport layer, TCTA (5 nm pure, 5 nm co-evaporated with the dye) and TPBI (co-evaporated with the dye) as the emissive hosts (where the first transports the holes and the latter the electrons), BAlQ as hole and exciton blocking layer and AlQ3 as the electron transport layer. Aluminum was used as cathode, in combination with the electron injection material LiF. The stack was applied in OLEDs on standard glass for modelling purposes, but also to serve as a reference to the structured OLEDs. Such green devices are fabricated regularly and have an efficacy of ˜45 cd/A at 1000 cd/m2 without further modifications.

Alternatively, embodiment cathode 3b may be formed by a metal, a combination of multiple metals, metal oxides, a metalorganic compound or even one or more organic layers, and may comprise an electron injection layer part formed by one or more optically reactive materials that facilitate charge injection. For instance, a 15 nm layer may be provided of a transparent layer sequence of Ba/Al/Ag, which can be capped with 20-30 nm of a high index organic, such as ZnS or ZnSe. Other suitable electron injection materials may include Ca, LiF, CsF, NaF, BaO, CaO, Li₂O, CsCO₃. Organic layers that facilitate electron injection may be based on variety of mechanisms, including, but not limited to, the formation of radicals when doped in an organic layer (N-DMBI) or the formation of a dipole layer that shifts the work function of the adjacent layer. The stack may be capped by a dense layer of SiN of about 100-200 nm, which provides a barrier to moisture and gasses. The top layers may be provided by an alternating stack of OCP (Organic Coating for Planarization) and SiN layers 6, ending in one or more layers to shield SiN layer 6 from outside influences such as scratches, for instance another OCP layer.

The stack 2 may be formed by a multi-layered structure comprising hole injection layers that may, by way of example, be formed by any of the following materials PEDOT:PSS; Polyaniline; m-MTDATA (4,4′,4″-Tris[(3-methylphenyl) phenylamino]triphenylamine); carbonitriles, such as HAT-CN, PPDN; phenazines (HATNA); quinoclimethanes, such as TCNQ and F4TCNQ; Phthaocyanine metalcomplexes (including Cu, Ti, Pt complexes); Aromatic amines including fluorene moieties, such as MeO-TPD, MeO-Spiro-TPD; benzidines (such as NTNPB, NPNPB). The OLED stack may furthermore comprise material layers known to the skilled person, e.g. hole transport layers; material layers for emissive phosphorescent dyes (e.g. Ir(III) emitters) and electron transport & hole blocking layers e.g. formed of Quinolinolato metal complexes, like Liq, BAlq; Benzimidazoles (such as TPBi, N-DMBi); Oxadiazoles (such as PBD, Bpy-OXD, BP-OXD-Bpy); Phenanthrolines (such as BCP, Bphen); Triazoles (such as TAZ, NTAZ); Pyridyl compounds (such as BP4mPy, TmPyPB, BP-OXD-Bpy); Pyridines (such as BmPyPhB, TpPyPB); Bathocuproines and Bathophenanthrolines, oxadiazoles, triazoles, quinoline aluminum salts.

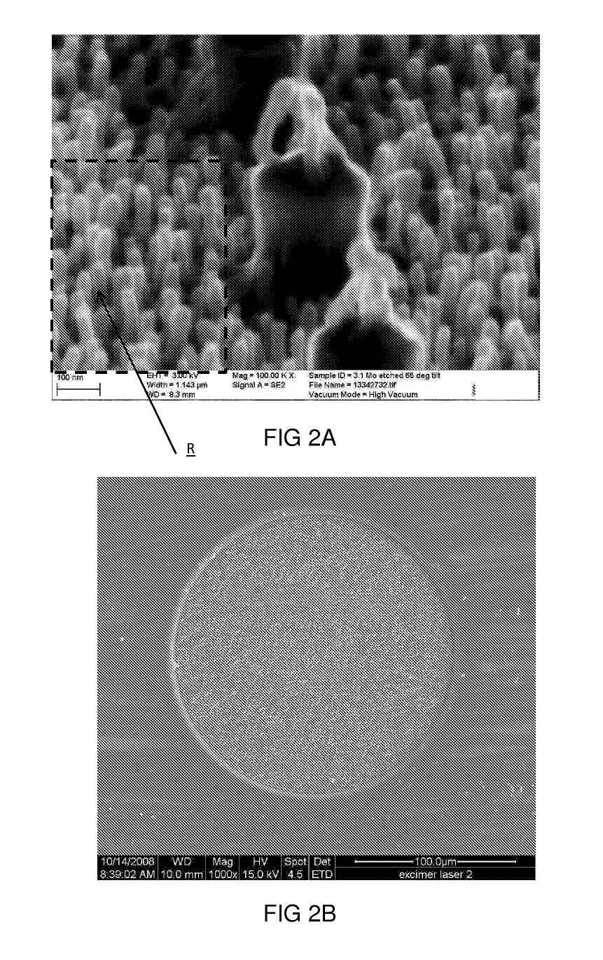

In FIG. 2A it is disclosed how the aperiodic pillar structure looks like in a SEM image of a polymer that is treated with a RIE-process, in particular, the structure in region R. Conditions of RIE may be adjusted to create higher structures—e.g. structures of several 100 nm high—up to or even beyond 1 micrometer. FIG. 2B shows a SEM image at 1000× of a polymer that exposed to laser irradiation of a KrF-excimer laser (248 nm), just below an ablation threshold; examples of such irradiation are found in H. Pzokian et al, J. Michromech, 22 (2012)035001.

It can be seen that on the substrate is formed a random nanopillar structure having a pillar height dimension between 50 and 1000 nanometer and a pitch in a range of 50-1000 nanometer.

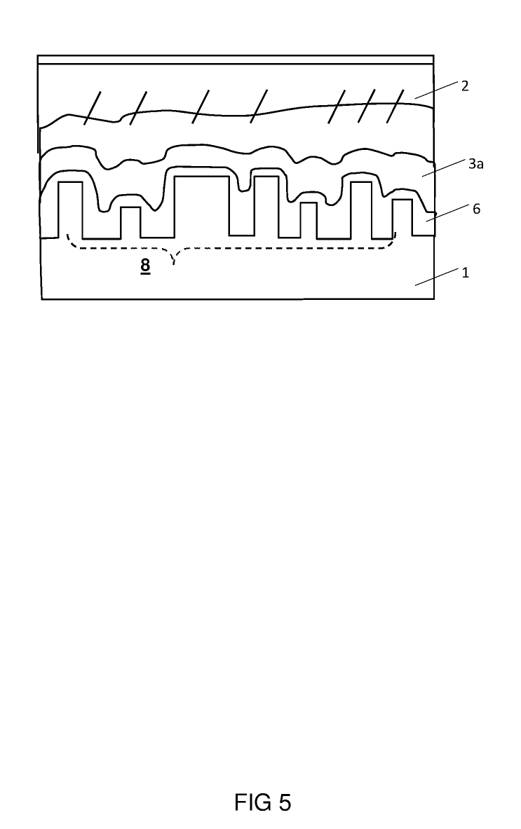

FIG. 5 shows an example, wherein these nano pillar structures are not planarized by the refractive coating and barrier layer 6, but will create a so-called corrugated OLED wherein the OLED including cathode 3a follows the topology imparted by the aperiodic, random nanopillar structure 8. The other layers in the OLED stack 2 are not shown for reasons of intelligibility. To this effect, the barrier layer is provided with at least 1 dyad or tryad of transparent inorganic and transparent organic layers with a total thickness of a few hundred nanometers to at most 20 microns, such that the nano-topology is not planarized and a non-planar interface remains with a height of the topology of at least 10% of the original height, more preferably 30%, even more preferably 50% of the nanopillar structure.

By such enhanced structures, the outcoupling efficiency of the device can be further enhanced because surface plasmons will be harvested (e.g. will counter-act cathode quenching). This effect may already be present for structures below 200 nm. The RIE may also (have to) be tuned to create less debris. Also, the RIE may be tuned to be a faster process. Also, the RIE may be tuned to have a higher or lower periodicity by tuning the density of particles.

Various ablation processes can be used to obtain similar results wherein the shielding particles shield the nanopillars from the ablation process, e.g.
3 min; 100 W; corresponding homogeneous etch rate HPR504 34 nm/min (100 sccm Ar, 15 sccm O2 and 5 sccm CHF3)
3 min; 300 W; corresponding homogeneous etch rate HPR504 69 nm/min (15 sccm O2 and 5 sccm CHF3)
9 min; 300 W; corresponding homogeneous etch rate HPR504 113 nm/min (15 sccm O2 and 5 sccm CHF3)

In another embodiment, the ablation process can be carried out by laser irradiation, to obtain a substrate having formed a random nanopillar structure thereon having a pillar height dimension between 50 and 1000 nanometer and a pitch in a range of 50-1000 nanometer.

In the range of 200-500 nm and above an increasing risk of shorts is present because the corrugation may be more difficult to conformably cover by the active layers of the OLED (all layers of the OLED, e.g. from bottom electrode to top electrode). Imperfect layer coverage may lead to irregular lateral electric field strengths, which may cause higher parasitic currents and eventually catastrophic shorts during device operation. On the other hand an irregular surface due to anti-reflective properties may also lead to enhanced outcoupling.

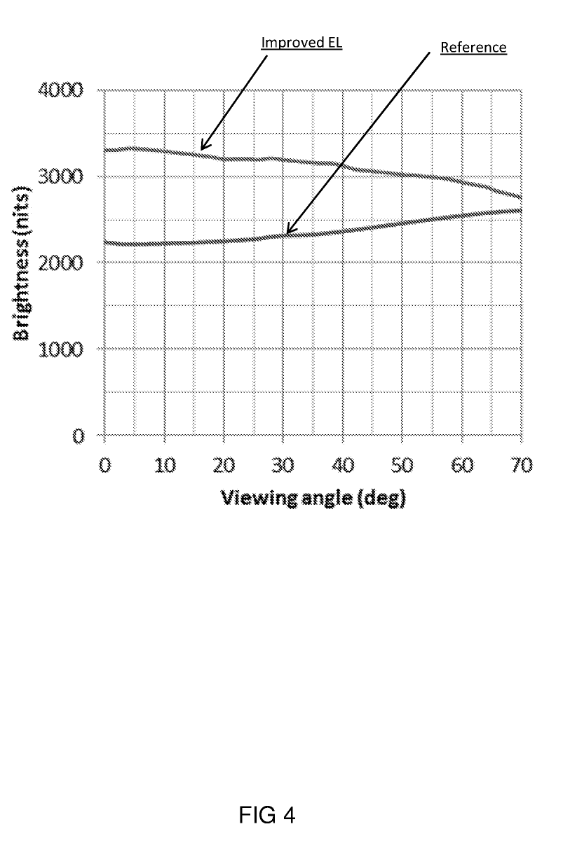

FIG. 4 shows a comparative example of increased electroluminescence of the OLED through use of the polymer substrate as provided. The example is provided by a RIE etching treatment of PEN for a period of about 3 minutes at 100 W, in an Oxygen plasma. Alternatively results may be obtained at 300 W*3min. The graph shows a measured brightness (cd/m2) as a function of external viewing angle (excluding cosine theta dependence). The electroluminescence response shows a clear signs of a redirection of emission into forward directed angles.

Data was obtained with a Display Metrology System (DMS, Autronic Melchers GmbH). The angle dependent luminance (in cd/m2) follows from the integration over the visible wavelength range of the overlap of the measured angle dependent spectral radiance S(λ,θ) (in W/sr m² nm) with the photopic curve S_{y}(λ) that has a power efficiency of 683 lm/W through the definition of the Candela SI unit. The measurement occurred at a current density of 5 mA/cm2.

Without being bound to theory, it is surmised that the process of creating the nanopillar structure by the ablation process is enhanced by the polymer substrate having a dispersion of inorganic shielding particles, wherein a periodic nanopillar structure is obtainable by an ablation process of the polymer substrate, wherein the shielding particles shield the nanopillars from the ablation process. While the particles may be selected and tuned to obtain a specific dimensioning of the nanopillar structure, the inorganic shielding particles are substantially made of an oxide of at least one element selected from the group consisting of Si, Al, Ti and Zr similar to the materials described in EP 1724613 A1. A compound that is available in organic substrate materials that are commercially available, e.g. a Dupont Q65 PEN foil, or other suitable substrate, e.g. a normally has a sufficient catalyst particle substance to obtain a relevant effect.

Particles may consist of polycondensation catalyst particles comprised of metallic components selected from the group consisting of antimony, lithium, germanium, cobalt, titanium, selenium, tin, zinc, aluminum, lead, iron, manganese, magnesium and calcium; and, employed in an amount ranging from 0.005 to 1% by weight based on the weight of the naphthalenic reactant, e.g. in the form of metal acetates of the type disclosed in U.S. Pat. No. 5,294,695

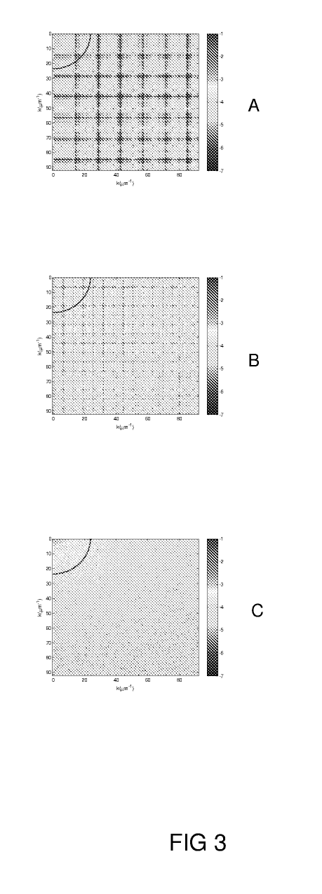

To demonstrate the impact of nano-pillar structure on the output of an OLED, full wave calculations were performed. The results are shown in FIG. 3, showing a calculation scheme for periodic structures of increasing periodicity, in this case, 1000 nm, 2000 nm and random structures. The figures are based on the visualization of the k-space and the determination of the number of modes present inside the light cone which would incouple light from free space modes into the modes of the multilayered system.

A figure of merit is defined by counting the number of modes in k-space inside the light cone for light of 532 nm wavelength (emission wavelength). The comparison is done between equally weighted k-space figures with following results:

| Periodicity (nm) | Figure of Merit |
|---|---|
| 1000 | 0.342 |
| 2000 | 0.498 |
| Random | 1.3453 |

It is noted that the numbers indicate a better outcoupling for structures with larger periods. Although a very large periodicity (p−>inf) could result in a similar k-space structure as for the random structure we need to take into account that light being emitted from the OLED has a certain coherence length on the order of 1 micron and therefore far spaced scatterers could present little to zero effect on the light emission.

It will be appreciated that while specific embodiments of the invention have been described above, that the invention may be practiced otherwise than as described. In addition, isolated features discussed with reference to different figures may be combined.

1. A method of manufacturing a barrier substrate for an organic light-emitting diode (OLED) system comprising:
providing a transparent polymer substrate;
forming a random nanopillar structure on the transparent polymer substrate wherein pillars of the nanopillar structure are formed using an ablation process, wherein the random nanopillar structure has:
a pillar height dimension in a range of 50 to 1000 nanometer; and
a pitch in a range of 50 to 1000 nanometer;
providing a transparent coating having a thickness in a range of 100 nm to 30 microns and having a refractive index matching an inorganic barrier layer; and
providing the inorganic barrier layer.

2. The method according to claim 1, further comprising providing a multi-layered structure having a semiconducting organic layer sandwiched between a first electron and a second electrode; wherein the inorganic barrier layer is interposed between the first electrode and the second electrode and the transparent polymer substrate on a second side of the inorganic barrier layer.

3. The method according to claim 2, wherein the inorganic barrier layer is provided in contact with the first electrode layer such the first electrode follows the topology imparted by the random nanopillar structure.

4. The method according to claim 1 wherein the ablation process is a Reactive Ion Etching (REI) process.

5. The method according to claim 4 wherein the RIE process is carried out by a plasma taken from the group consisting of: CHF3, Ar, O2; and
wherein the plasma is delivered at a power setting of 50-500 W, and time duration range of 0.1-10 minutes.

6. A method of manufacturing a barrier substrate for an organic light-emitting diode (OLED) system, carried out in a roll to roll process, comprising:
providing a transparent polymer substrate on a roll;
unrolling the transparent polymer substrate;
forming a random nanopillar structure on the transparent polymer substrate wherein pillars of the nanopillar structure are formed using an ablation process, wherein the random nanopillar structure has:
a pillar height dimension in a range of 50 to 1000 nanometer; and
a pitch in a range of 50 to 1000 nanometer;
providing a transparent coating having a thickness in a range of 100 nm to 30 microns and having a refractive index matching an inorganic barrier layer;
providing the inorganic barrier layer to render a finished barrier substrate on a roll.

7. The method according to claim 6 wherein the transparent polymer substrate comprises a dispersion of inorganic shielding particles.

8. The method according to claim 7, wherein the inorganic shielding particles shield the nano pillars from the ablation process and are substantially made of an oxide of at least one element selected from the group consisting of: Si, Al, Ti and Zr.

9. The method according to claim 8, wherein an average particle diameter of the shielding particles is in a range of 5-100 nm.

10. A method according to claim 6 wherein the ablation process is a laser process.

11. The method of claim 6 wherein the transparent polymer substrate is made from polyethylene terephthalate (PET).

12. The method of claim 6 wherein the transparent polymer substrate is made from polyethylene naphthalate (PEN).

13. The method according to claim 1 wherein the transparent polymer substrate comprises a dispersion of inorganic shielding particles.

14. The method according to claim 13, wherein the inorganic shielding particles shield the nano pillars from the ablation process and are substantially made of an oxide of at least one element selected from the group consisting of: Si, Al, Ti and Zr.

15. The method according to claim 14, wherein an average particle diameter of the shielding particles is in a range of 5-100 nm.

16. The method according to claim 1 wherein the ablation process is a laser process.

17. The method of claim 1 wherein the transparent polymer substrate is made from polyethylene terephthalate (PET).

18. The method of claim 1 wherein the transparent polymer substrate is made from polyethylene naphthalate (PEN).

17. The method of claim 5 wherein the plasma is delivered at a power setting of between 100 and 300 W.

18. The method of claim 5 wherein the plasma is delivered for a duration range of between 0.5 and 5 minutes.
